(19) United States
(12) Patent Application Publication
(10) Pub. No.: US 2024/0021552 A1
(43) Pub. Date: Jan. 18, 2024

(54) CHIP PACKAGE UNIT, METHOD OF MANUFACTURING THE SAME, AND PACKAGE STRUCTURE FORMED BY STACKING THE SAME

(71) Applicant: WALTON ADVANCED ENGINEERING, INC., Kaohsiung (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/220,245

(22) Filed: Jul. 10, 2023

(30) Foreign Application Priority Data
Jul. 12, 2022 (TW) 111126109

(51) Int. Cl. H01L 23/00; H01L 25/065; H01L 21/78

(52) U.S. Cl. CPC H01L 24/06; H01L 24/02; H01L 24/04; H01L 24/05; H01L 24/16; H01L 24/14; H01L 24/13; H01L 25/0657; H01L 21/78; H01L 2225/06513; H01L 2225/06517; H01L 2225/06527; H01L 2225/06565; H01L 2224/02371; H01L 2224/02331; H01L 2224/02381; H01L 2224/02375; H01L 2224/0401; H01L 2224/05008; H01L 2224/05073; H01L 2224/05548; H01L 2224/05573; H01L 2224/06182; H01L 2224/13024; H01L 2224/13021; H01L 2224/14181; H01L 2224/16145; H01L 2224/16225

(57) ABSTRACT

A chip package unit, a method of manufacturing the same, and a package structure formed by stacking the same are provided. The chip package unit is formed by cutting of a wafer separately. The chip package unit includes a chip, a first redistribution layer (RDL), a second RDL, and at least one first circuit layer. The first circuit layer is electrically connected with and disposed between a first conductive circuit and a second conductive circuit. The first circuit layer is located at least one first lateral side of the chip, at least one second lateral side of the first RDL, and at least one third lateral side of the second RDL. The chip can be electrically connected with the outside by the first conductive circuit or the second conductive circuit. Thereby manufacturing process is simplified and manufacturing cost is further reduced.

### CROSS-REFERENCE TO RELATED APPLICATIONS

This non-provisional application claims priority under 35 U.S.C. § 119(a) on Patent Application No(s). 111126109 filed in Taiwan, R.O.C. on Jul. 12, 2022, the entire contents of which are hereby incorporated by reference.

### BACKGROUND OF THE INVENTION

The present invention relates to a chip package, especially to a chip package unit, a method of manufacturing the same, and a package structure formed by stacking the same in which a circuit layer is disposed on a lateral side of a chip so that a first redistribution layer (RDL) and a second RDL respectively arranged at a front surface and a back surface of the chip are electrically connected.

In a conventional chip package, a through silicon via (TSV) is a vertical electrical connection (via) that passes through a chip (or die) from a front surface to a back surface completely. Thereby the front surface or the back surface of the chip package can be electrically connected to the outside. However, a formation process of TSV is labor and time consuming. The TSV also increases difficulty in internal circuit design of the chip. For example, the design of the internal circuit in the chip needs to avoid positions of the TSV so that manufacturing cost of the chip package is increased.

### SUMMARY OF THE INVENTION

Therefore, it is a primary object of the present invention to provide a chip package unit, a method of manufacturing the same, and a package structure formed by stacking the same. The chip package unit is formed by cutting of a wafer separately. The chip package unit includes a chip, a first redistribution layer (RDL), a second RDL, and at least one first circuit layer. The first circuit layer is electrically connected with and disposed between a first conductive circuit and a second conductive circuit. The first circuit layer is located at least one first lateral side of the chip, at least one second lateral side of the first RDL, and at least one third lateral side of the second RDL. The chip can be electrically connected with the outside by the first conductive circuit or the second conductive circuit. Thereby manufacturing process is simplified and manufacturing cost is further reduced.

In order to achieve the above object, a chip package unit according to the present invention is provided with a first surface and a second surface opposite to the first surface. The chip package unit includes a chip, a first redistribution layer (RDL), a second RDL, and at least one first circuit layer. The chip is provided with a third surface, a fourth surface, and at least one first lateral side. At least one die pad and at least one chip protection layer are disposed on the third surface while the fourth surface is disposed opposite to the third surface. The first RDL is located at the third surface of the chip and composed of at least one first dielectric layer, at least one bump, at least one third dielectric layer, at least one first conductive circuit, and at least one second lateral side arranged over the third surface in turn. The first dielectric layer is covering the third surface of the chip correspondingly and provided with a surface and at least one groove which is corresponding to the die pad of the chip. The bump is disposed in the groove of the first dielectric layer and electrically connected with the die pad of the chip. The third dielectric layer is arranged at the surface of the first dielectric layer and provided with a surface. The first conductive circuit is mounted to the surface of the first dielectric layer, electrically connected with the bump, and having an exposed surface. The second RDL is located at the fourth surface of the chip and composed of at least one second dielectric layer, at least one second conductive circuit, and at least one third lateral side arranged over the fourth surface in turn. The second dielectric layer is covering the fourth surface of the chip correspondingly and provided with a surface. The second conductive circuit is disposed on the surface of the second dielectric layer and having an exposed surface. The first circuit layer is electrically connected with and disposed between the first conductive circuit and the second conductive circuit. The first circuit layer is located at the first lateral side of the chip, the second lateral side of the first RDL, and the third lateral side of the second RDL. The chip can be electrically connected with the outside by the first conductive circuit or the second conductive circuit. The chip package unit is further formed by cutting of a wafer separately and the chip is having a seventh surface and an eighth surface opposite to the seventh surface. A plurality of the chip package units is arranged in an array and adjacent to one another on the wafer. A cut area is formed between the two adjacent chip package units and at least one conducting through hole is arranged at the cut area and axially penetrating the seventh surface and the eight surface. The conducting through hole is located at an outer edge of the first lateral side of the chip, the second lateral side of the first RDL, and the third lateral side of the second RDL of the chip package unit. The conducting through hole includes an axial connecting circuit therein and the axial connecting circuit is electrically connected with the first conductive circuit and the second conductive circuit of the chip package unit. The cutting is performed by using cutting tools to cut the wafer along the respective cut areas. After the cutting, a cut path with a width smaller than that of the cut area is formed on the respective cut areas. At the same time, a part of the respective conducting through holes and a part of the respective axial connecting circuits are also cut. The rest part of the respective axial connecting circuits and the rest part of the respective conducting through holes are retained at an outer edge of the respective chip packages to form the respective first circuit layers of the respective chip package units.

A method of manufacturing chip package units according to the present invention includes the following steps. Step S1: providing a wafer which includes a seventh surface, an eighth surface opposite to the seventh surface, and a plurality of the chip package units arranged in an array and adjacent to one another. Each of the chip package units is composed of a chip, a first RDL, and a second RDL. The chip consists of a third surface provided with at least one die pad and at least one chip protection layer, a fourth surface opposite to the third surface, and at least one first lateral side. The first RDL is located at the third surface of the chip and composed of at least one first dielectric layer, at least one bump, at least one third dielectric layer, at least one first conductive circuit, and at least one second lateral side arranged over the third surface in turn. The first dielectric layer is covering the third surface of the chip correspondingly and provided with a surface and at least one groove which is corresponding to the die pad of the chip. The bump is mounted in the groove of the first dielectric layer and electrically connected with the die pad of the chip. The third dielectric layer is arranged at the surface of the first dielectric layer and provided with a surface. The first conductive circuit is mounted to the surface of the first dielectric layer, electrically connected with the bump and having an exposed surface. The second RDL is located at the fourth surface of the chip and composed of at least one second dielectric layer, at least one second conductive circuit, and at least one third lateral side arranged over the fourth surface in turn. The second dielectric layer is covering the fourth surface of the chip correspondingly and provided with a surface. The second conductive circuit is disposed on the surface of the second dielectric layer and having an exposed surface. A cut area is formed between the two adjacent chip package units and at least one conducting through hole is arranged at the cut area and axially penetrating the seventh surface and the eight surface. The conducting through hole is located at an outer edge of the first lateral side of the chip, the second lateral side of the first RDL, and the third lateral side of the second RDL of the chip package unit. The conducting through hole includes an axial connecting circuit therein and the axial connecting circuit is electrically connected with the first conductive circuit and the second conductive circuit of the chip package unit.

Step S2: cutting the wafer along the respective cut areas on the wafer by using cutting tools. After being cut, a cut path with a width smaller than that of the cut area is formed on the respective cut areas. At the same time, a part of the respective conducting through holes and a part of the respective the axial connecting circuits are also cut. The rest part of the respective the axial connecting circuits and the rest part of the respective conducting through holes are kept at an outer edge of the respective chip packages to form at least one first circuit layer of the respective chip package units. The first circuit layer is electrically connected with and arranged between the first conductive circuit and the second conductive circuit. The first circuit layer is located at the first lateral side of the chip, the second lateral side of the first RDL, and the third lateral side of the second RDL. The chip can be electrically connected with the outside by the first conductive circuit or the second conductive circuit.

Step S3: getting a plurality of the chip package units after completing the cutting of the wafer.

A package structure formed by stacking chip package units according to the present invention includes at least one substrate, at least one second circuit layer, at least one third conductive circuit, at least two chip package units, and at least one insulating layer. The substrate is provided with a fifth surface and a sixth surface opposite to each other while at least one blind hole is formed on the fifth surface of the substrate. The second circuit layer is disposed on the sixth surface of the substrate and extending to an inner wall surface of the blind hole of the substrate. The third conductive circuit is electrically connected with and arranged at the second circuit layer. The two chip package units are stacked vertically while an upper chip package unit and a lower chip package unit of the two chip package units are electrically connected by at least one fourth conductive circuit which is electrically connected with the second conductive circuit of the upper chip package unit and the first conductive circuit of the lower chip package unit. The insulating layer is arranged at the substrate and covering the respective chip package units. The chip package unit is electrically connected to the outside by the second circuit layer.

### BRIEF DESCRIPTION OF THE DRAWINGS

FIG. 1 is a side view of a longitudinal section of an embodiment of a chip package unit according to the present invention;

FIG. 2 is a side view of a longitudinal section of a wafer according to the present invention;

FIG. 3 is a partial enlarged view of the embodiment in FIG. 2;

FIG. 4 is a side view of a longitudinal section of a chip package unit without a solder ball of an embodiment according to the present invention;

FIG. 5 is a top view of a wafer of an embodiment according to the present invention;

FIG. 6 is a partial enlarged view of the embodiment in FIG. 5 according to the present invention;

FIG. 7 is a top view of a chip package unit of an embodiment (in which a first redistribution layer is represented by a solid line) according to the present invention;

FIG. 8 is a top view of a chip package unit of an embodiment (in which a second redistribution layer is represented by a dotted line) according to the present invention;

FIG. 9 is a side view of a longitudinal section of a package structure of an embodiment according to the present invention;

FIG. 10 is a side view of a longitudinal section of a package structure which includes three chip package units of an embodiment according to the present invention.

### DETAILED DESCRIPTION OF THE PREFERRED EMBODIMENT

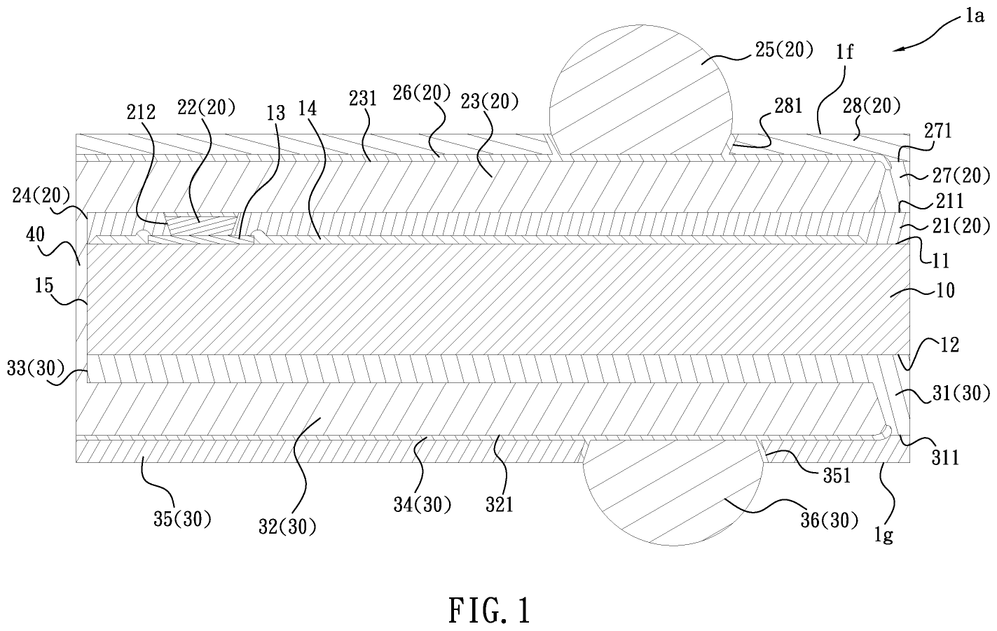

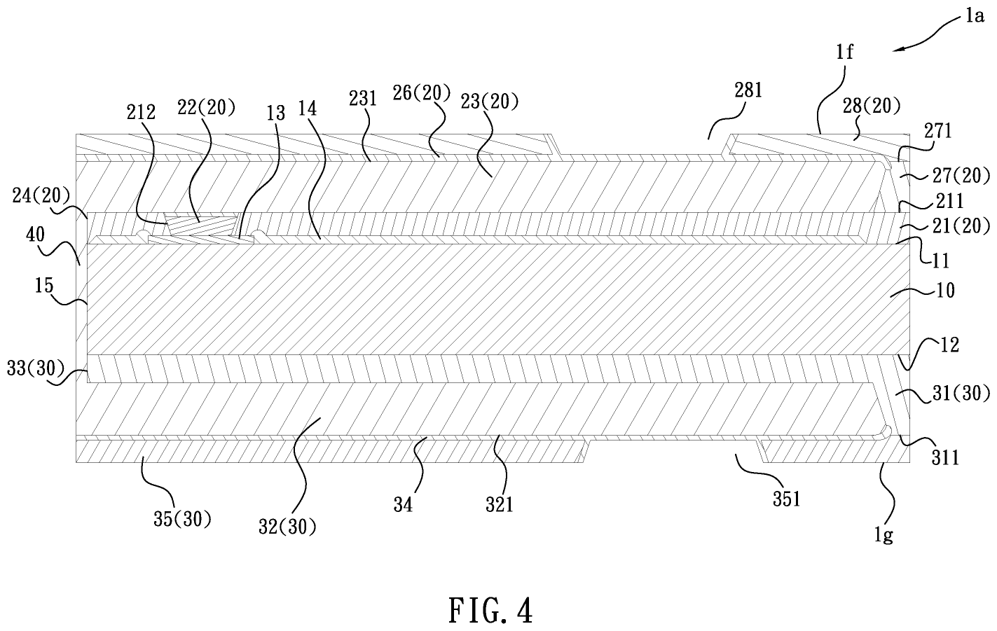

Refer to FIG. 1 and FIG. 4, a chip package unit 1a according to the present invention is provided with a first surface 1f and a second surface 1g opposite to the first surface 1f. The chip package unit 1a includes a chip 10, a first redistribution layer (RDL) 20, a second RDL 30, and at least one first circuit layer 40. The chip 10 is provided with a third surface 11, a fourth surface 12, and at least one first lateral side 15. At least one die pad 13 and at least one chip protection layer 14 are disposed on the third surface 11 while the fourth surface 12 is disposed opposite to the third surface 11.

The first RDL 20 is located at the third surface 11 of the chip 10 and composed of at least one first dielectric layer 21, at least one bump 22, at least one third dielectric layer 27, at least one first conductive circuit 23, and at least one second lateral side 24 arranged over the third surface 11 in turn. The first dielectric layer 21 is covering the third surface 11 of the chip 10 correspondingly and provided with a surface 211 and at least one groove 212 which is corresponding to the die pad 13 of the chip 10. The respective bumps 22 are disposed in the respective grooves 212 of the first dielectric layer 21 and electrically connected with the respective die pads 13 of the chip 10. The third dielectric layer 27 is arranged at the surface 211 of the first dielectric layer 21 and provided with a surface 271. The first conductive circuit 23 is mounted to the surface 211 of the first dielectric layer 21, electrically connected with the bump 22, and having an exposed surface 231 for electrical connection to the outside.

The second RDL 30 is located at the fourth surface 12 of the chip 10 and composed of at least one second dielectric layer 31, at least one second conductive circuit 32, and at least one third lateral side 33 arranged over the fourth surface 12 in turn. The second dielectric layer 31 is covering the fourth surface 12 of the chip 10 correspondingly and provided with a surface 311. The respective second conductive circuits 32 are disposed on the surface 311 of the second dielectric layer 31 and having an exposed surface 321 for electrical connection to the outside.

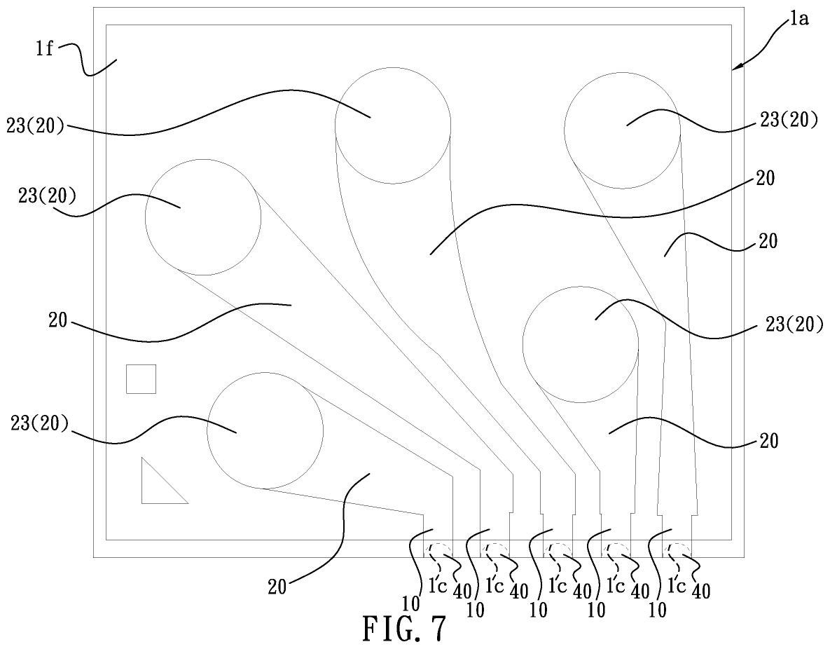

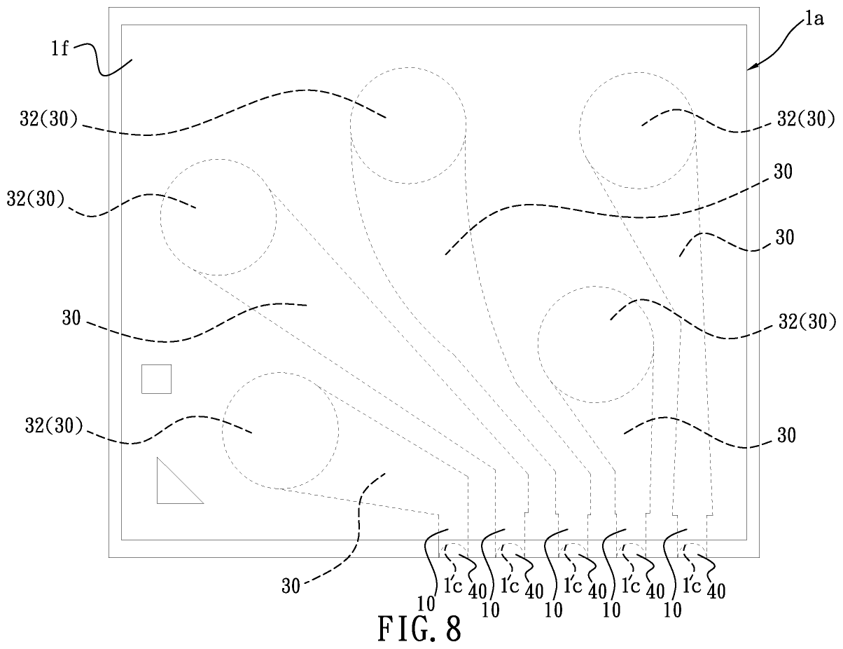

The first RDL 20 is arranged opposite to the second RDL 30. When the first RDL 20 is located on one surface of the chip package unit 1a (such as the first surface 1f), as shown in FIG. 7, the second RDL 30 is disposed on the other surface of the chip package unit 1a, opposite to the surface (such as the first surface 1f) of the chip package unit 1a, as shown in FIG. 8.

The first circuit layer 40 is electrically connected with and disposed between the first conductive circuit 23 and the second conductive circuit 32. The first circuit layer 40 is located at the first lateral side 15 of the chip 10, the second lateral side 24 of the first RDL 20, and the third lateral side 33 of the second RDL 30. The chip 10 can be electrically connected with the outside by the first conductive circuit 23 or the second conductive circuit 32, as shown in FIG. 1 and FIG. 4.

The first RDL 20 further includes at least one first protective layer 26 which is arranged at the surface 231 of the first conductive circuit 23.

The second RDL 30 further includes at least one second protective layer 34 which is arranged at the surface 321 of the second conductive circuit 32.

The first RDL 20 further includes at least one fifth dielectric layer 28 which is disposed on the surface 271 of the third dielectric layer 27 and provided with at least one first opening 281 for allowing the first conductive circuit 23 to be exposed and electrically connected to the outside.

The second RDL 30 further includes at least one fourth dielectric layer 35 which is disposed on the surface 311 of the second dielectric layer 31 and provided with at least one second opening 351 for allowing the second conductive circuit 32 to be exposed and electrically connected to the outside.

The first RDL 20 further includes at least one first solder ball 25 which is mounted to the first opening 281 of the fifth dielectric layer 28. Thus the chip package unit 1a is welded to and electrically connected with external electrical components by the first solder ball 25.

The second RDL 30 further includes at least one second solder ball 36 which is mounted to the second opening 351 of the fourth dielectric layer 35. Thus the chip package unit 1a is welded to and electrically connected with external electrical components by the second solder ball 36.

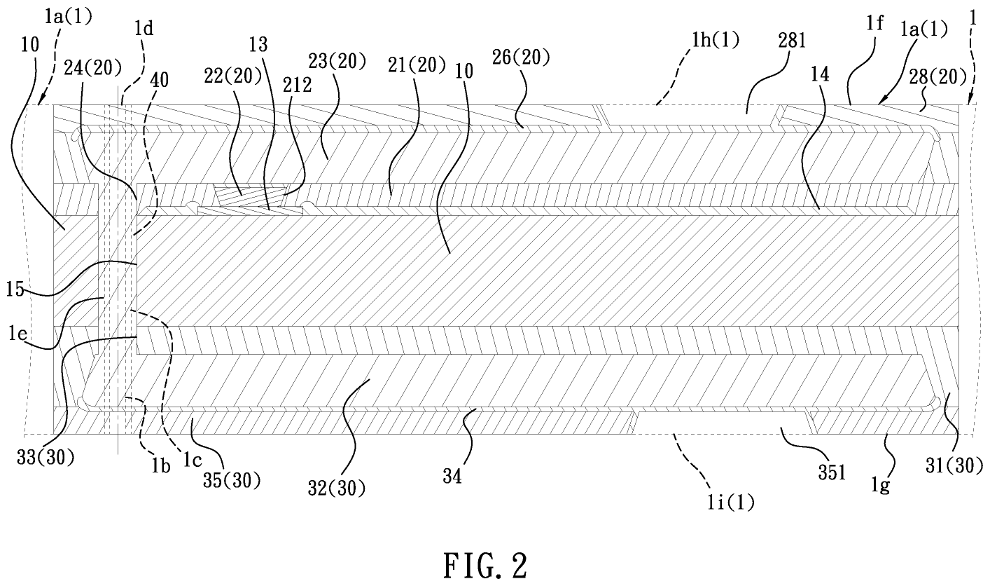

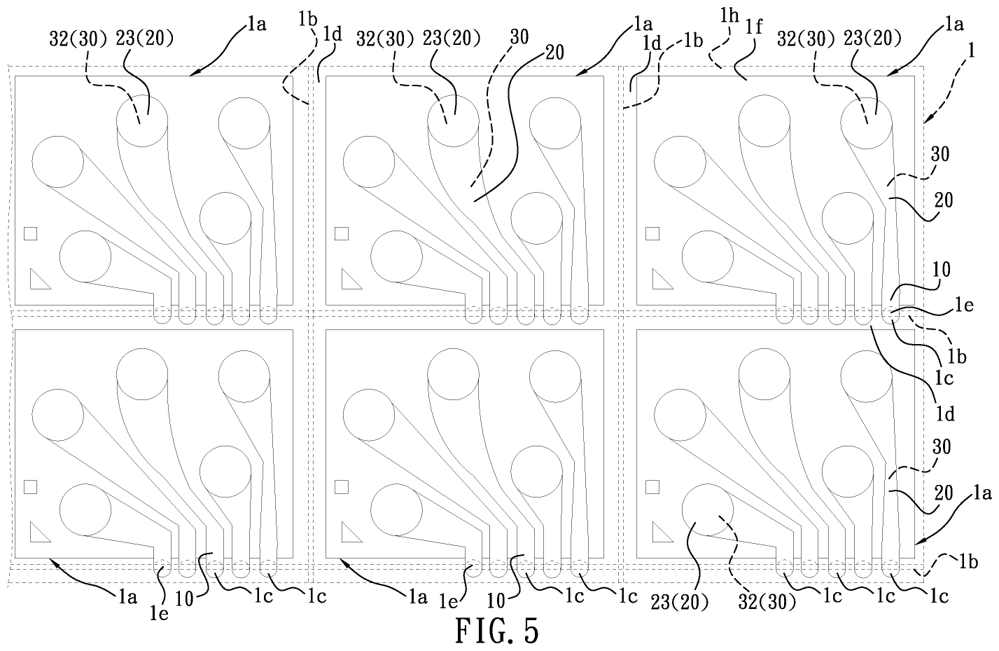

Refer to FIG. 2-8, a method of manufacturing chip package units according to the present invention includes the following steps.

Step S1: providing a wafer 1 which includes a seventh surface 1h, an eighth surface 1i opposite to the seventh surface 1h, and a plurality of the chip package units 1a arranged in an array and adjacent to one another. Each of the chip package units 1a consists of a chip 10, a first RDL 20, and a second RDL 30. The chip 10 is composed of a third surface 11, a fourth surface 12 opposite to the third surface 11, at least one die pad 13 and at least one chip protection layer 14 both of which are arranged at the third surface 11, and at least one first lateral side 15. The first RDL 20 is located at the third surface 11 of the chip 10 and composed of at least one first dielectric layer 21, at least one bump 22, at least one third dielectric layer 27, at least one first conductive circuit 23, and at least one second lateral side 24 arranged over the third surface 11 in turn. The first dielectric layer 21 is covering the third surface 11 of the chip 10 correspondingly and provided with a surface 211 and at least one groove 212 which is corresponding to the die pad 13 of the chip 10. The respective bumps 22 are disposed in the respective grooves 212 of the first dielectric layer 21 and electrically connected with the respective die pads 13 of the chip 10. The third dielectric layer 27 is arranged at the surface 211 of the first dielectric layer 21 and provided with a surface 271. The first conductive circuit 23 is mounted to the surface 211 of the first dielectric layer 21, electrically connected with the bump 22, and having an exposed surface 231 for electrical connection to the outside. The second RDL 30 is located at the fourth surface 12 of the chip 10 and composed of at least one second dielectric layer 31, at least one second conductive circuit 32, and at least one third lateral side 33 arranged over the fourth surface 12 in turn. The second dielectric layer 31 is covering the fourth surface 12 of the chip 10 correspondingly and provided with a surface 311. The respective second conductive circuits 32 are disposed on the surface 311 of the second dielectric layer 31 and having an exposed surface 321, as shown in FIG. 4. A cut area id is formed between the two adjacent chip package units 1a and at least one conducting through hole 1c arranged at the cut area 1d and axially penetrating the seventh surface 1h and the eight surface 1i. The respective conducting through holes 1c are located at an outer edge of the first lateral side 15 of the chip 10, the second lateral side 24 of the first RDL 20, and the third lateral side 33 of the second RDL 30 of the chip package unit 1a. The conducting through hole 1c includes an axial connecting circuit 1e therein and the axial connecting circuit 1e is electrically connected with the first conductive circuit 23 and the second conductive circuit 32 of the chip package unit 1a.

Step S2: cutting the wafer 1 along the respective cut areas 1d on the wafer 1 by using cutting tools (not shown in figures). After being cut, a cut path 1b with a width smaller than a width of the cut area 1d is formed on the respective cut areas id. At the same time, a part of the respective conducting through holes 1c and a part of the respective the axial connecting circuits 1e are also cut. The rest part of the respective axial connecting circuits 1e and the rest part of the respective conducting through holes 1c are retained at an outer edge of the respective chip packages 1a to form at least one first circuit layer 40 of the respective chip package units 1a. The first circuit layer 40 is electrically connected with and arranged between the first conductive circuit 23 and the second conductive circuit 32. The first circuit layer 40 is located at the first lateral side 15 of the chip 10, the second lateral side 24 of the first RDL 20, and the third lateral side 33 of the second RDL 30. The chip 10 can be electrically connected with the outside by the first conductive circuit 23 or the second conductive circuit 32.

Step S3: getting a plurality of the chip package units 1a after completing the cutting of the wafer 1.

The step S1 further includes a step of removing a redundant part of both the first conductive circuit 23 and the third dielectric layer 27 of the chip package unit 1a at the same time by circuit grinding technique so that the surface 231 of the first conductive circuit 23 is flush with a surface 272 of the third dielectric layer 27 (not shown in figure). A redundant part of the second conductive circuit 32 and a redundant part of the second dielectric layer 31 of the chip package unit 1a are also removed at the same time by circuit grinding technique so that the surface 321 of the second conductive circuit 32 is flush with a surface 311 of the second dielectric layer 31 (not shown in figure). The above steps are common on RDL related techniques.

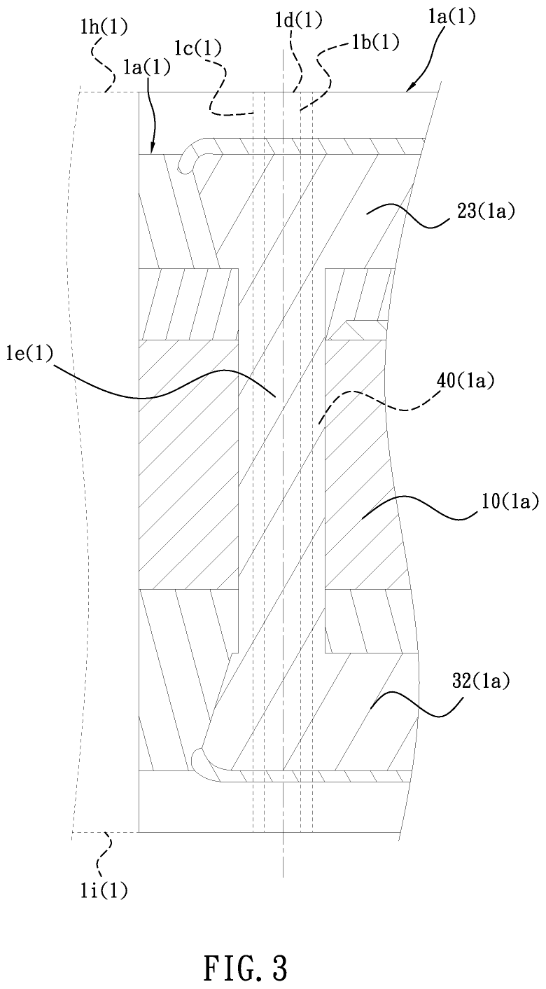

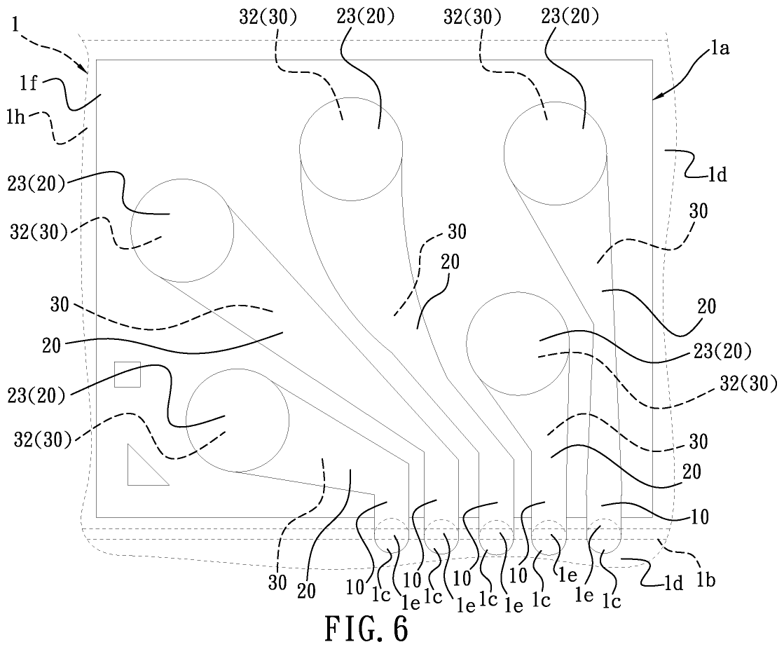

Refer to FIG. 3 and FIG. 6, a diameter of the conducting through hole 1c of the wafer 1 is larger than a width of the cut path 1b, but not limited. During formation of the cut path 1b, a part of the conducting through hole 1c and a part of the axial connecting circuit 1e are also retained at the same time.

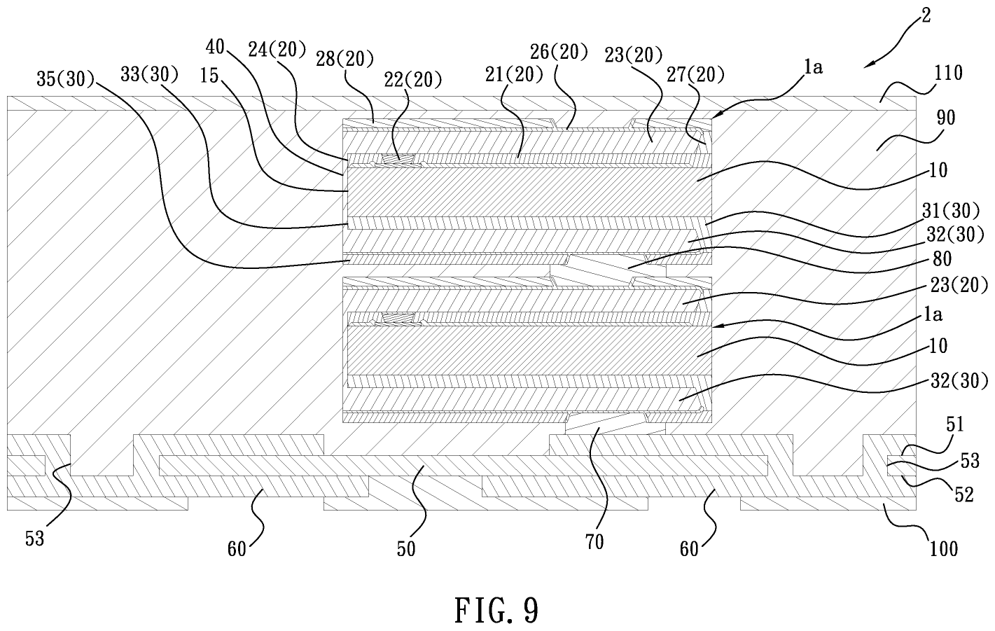

Refer to FIG. 9, a package structure 2 formed by stacking chip package units 1a is provided. The package structure 2 includes at least one substrate 50, at least one second circuit layer 60, at least one third conductive circuit 70, at least two chip package units 1a, and at least one insulating layer 90. The substrate 50 is provided with a fifth surface 51 and a sixth surface 61 opposite to each other while at least one blind hole 53 is formed on the fifth surface 51 of the substrate 50. The second circuit layer 60 is disposed on the sixth surface 52 of the substrate 50 and extending to an inner wall surface of the blind hole 53 of the substrate 50. The third conductive circuit 70 is electrically connected with and arranged at the second circuit layer 60. The two chip package units 1a are stacked vertically while an upper chip package unit 1a and a lower chip package unit 1a are electrically connected by at least one fourth conductive circuit 80 which is electrically connected with the second conductive circuit 32 of the upper chip package unit 1a and the first conductive circuit 23 of the lower chip package unit 1a. The insulating layer 90 is arranged at the substrate 50 and covering the respective chip package units 1a. The chip package unit 1a is electrically connected to the outside by the second circuit layer 60. The package structure 2 further includes an outer bottom protective layer 100 and an outer top protective lay 110 respectively on a bottom and a top thereof for increasing structural strength.

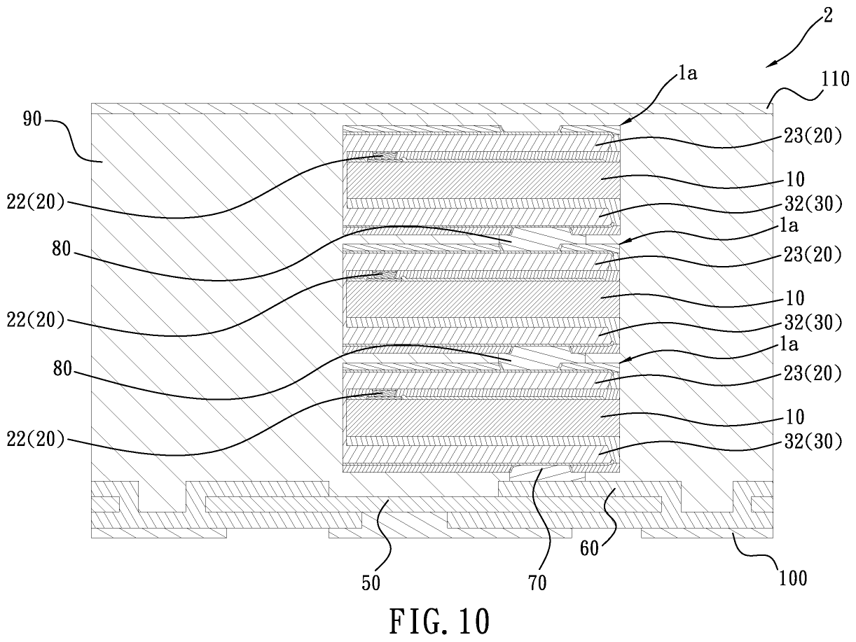

Refer to FIG. 10, the package structure 2 includes the three chip package units 1a in order to increase computing performance and product competitiveness on the market.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A chip package unit which is provided with a first surface and a second surface opposite to the first surface comprising:
a chip which includes a third surface provided with at least one die pad and at least one chip protection layer, a fourth surface opposite to the third surface, and at least one first lateral side;
a first redistribution layer (RDL) located at the third surface of the chip and composed of at least one first dielectric layer, at least one bump, at least one third dielectric layer, at least one first conductive circuit, and at least one second lateral side arranged over the third surface in turn; wherein the first dielectric layer is covering the third surface of the chip correspondingly and provided with a surface and at least one groove which is corresponding to the die pad of the chip; wherein the bump is disposed in the groove of the first dielectric layer and electrically connected with the die pad of the chip; wherein the third dielectric layer is arranged at the surface of the first dielectric layer and provided with a surface; wherein the first conductive circuit is mounted to the surface of the first dielectric layer, electrically connected with the bump, and having an exposed surface; and
a second redistribution layer (RDL) which is located at the fourth surface of the chip and composed of at least one second dielectric layer, at least one second conductive circuit, and at least one third lateral side arranged over the fourth surface in turn; wherein the second dielectric layer is covering the fourth surface of the chip correspondingly and provided with a surface; wherein the second conductive circuit is disposed on the surface of the second dielectric layer and having an exposed surface; and
at least one first circuit layer which is electrically connected with and disposed between the first conductive circuit and the second conductive circuit; the first circuit layer is located at the first lateral side of the chip, the second lateral side of the first RDL, and the third lateral side of the second RDL;
wherein the chip is electrically connected with the outside by the first conductive circuit or the second conductive circuit; wherein the chip package unit is formed by cutting of a wafer separately and the chip is having a seventh surface and an eighth surface opposite to the seventh surface; wherein a plurality of the chip package units is arranged in an array and adjacent to one another on the wafer while a cut area is formed between the two adjacent chip package units and at least one conducting through hole is arranged at the cut area and axially penetrating the seventh surface and the eight surface; the conducting through hole is located at an outer edge of the first lateral side of the chip, the second lateral side of the first RDL, and the third lateral side of the second RDL of the chip package unit; the conducting through hole includes an axial connecting circuit therein and the axial connecting circuit is electrically connected with the first conductive circuit and the second conductive circuit of the chip package unit; wherein the cutting is performed by using cutting tools to cut the wafer along the respective cut areas of the wafer; wherein a cut path with a width smaller than a width of the cut area is formed on the respective cut areas of the wafer after the cutting; at the same time as formation of the cut path, a part of the conducting through hole and a part of the axial connecting circuit are cut while the rest part of the axial connecting circuit and the rest part of the conducting through hole are kept at an outer edge of the chip package to form the first circuit layer of the chip package unit.

2. The chip package unit as claimed in claim 1, wherein the first RDL further includes at least one first protective layer which is arranged at the surface of the first conductive circuit.

3. The chip package unit as claimed in claim 1, wherein the second RDL further includes at least one second protective layer which is arranged at the surface of the second conductive circuit.

4. The chip package unit as claimed in claim 1, wherein the first RDL further includes at least one fifth dielectric layer which is disposed on the surface of the third dielectric layer and provided with at least one first opening for allowing the first conductive circuit to be exposed.

5. The chip package unit as claimed in claim 1, wherein the second RDL further includes at least one fourth dielectric layer which is disposed on the surface of the second dielectric layer and provided with at least one second opening for allowing the second conductive circuit to be exposed.

6. The chip package unit as claimed in claim 4, wherein the first RDL further includes at least one first solder ball which is mounted to the first opening of the fifth dielectric layer.

7. The chip package unit as claimed in claim 5, wherein the second RDL further includes at least one second solder ball which is mounted to the second opening of the fourth dielectric layer.

8. The chip package unit as claimed in claim 1, wherein a diameter of the conducting through hole of the wafer is larger than a width of the cut path.

9. A method of manufacturing chip package units comprising the steps of:
Step S1: providing a wafer which includes a seventh surface, an eighth surface opposite to the seventh surface, and a plurality of the chip package units arranged in an array and adjacent to one another; each of the chip package units is composed of a chip, a first redistribution layer (RDL), and a second redistribution layer (RDL); wherein the chip consists of a third surface provided with at least one die pad and at least one chip protection layer, a fourth surface opposite to the third surface, and at least one first lateral side; wherein the first RDL is located at the third surface of the chip and composed of at least one first dielectric layer, at least one bump, at least one third dielectric layer, at least one first conductive circuit, and at least one second lateral side arranged over the third surface in turn; wherein the first dielectric layer is covering the third surface of the chip correspondingly and provided with a surface and at least one groove which is corresponding to the die pad of the chip; wherein the bump is mounted in the groove of the first dielectric layer and electrically connected with the die pad of the chip; wherein the third dielectric layer is arranged at the surface of the first dielectric layer and provided with a surface; wherein the first conductive circuit is mounted to the surface of the first dielectric layer, electrically connected with the bump, and having an exposed surface; wherein the second RDL is located at the fourth surface of the chip and composed of at least one second dielectric layer, at least one second conductive circuit, and at least one third lateral side arranged over the fourth surface in turn; wherein the second dielectric layer is covering the fourth surface of the chip correspondingly and provided with a surface; wherein the second conductive circuit is disposed on the surface of the second dielectric layer and having an exposed surface; wherein a cut area is formed between the two adjacent chip package units and at least one conducting through hole is arranged at the cut area and axially penetrating the seventh surface and the eight surface; wherein the conducting through hole is located at an outer edge of the first lateral side of the chip, the second lateral side of the first RDL, and the third lateral side of the second RDL of the chip package unit; the conducting through hole includes an axial connecting circuit therein and the axial connecting circuit 1e is electrically connected with the first conductive circuit and the second conductive circuit of the chip package unit;
Step S2: cutting the wafer along the respective cut areas on the wafer by using cutting tools and a cut path with a width smaller than a width of the cut area is formed on the respective cut areas after the cutting; a part of the conducting through hole and a part of the axial connecting circuit are also cut at the same time while the rest part of the axial connecting circuit and the rest part of the conducting through hole are kept at an outer edge of the chip package to form at least one first circuit layer of the chip package unit; wherein the first circuit layer is electrically connected with and arranged between the first conductive circuit and the second conductive circuit; the first circuit layer is located at the first lateral side of the chip, the second lateral side of the first RDL, and the third lateral side of the second RDL; wherein the chip is electrically connected with the outside by the first conductive circuit or the second conductive circuit; and
Step S3: getting a plurality of the chip package units after completing the cutting of the wafer.

10. The method as claimed in claim 9, wherein the step S1 further includes a step of removing a redundant part of the first conductive circuit and a redundant part of the third dielectric layer of the chip package unit at the same time by circuit grinding technique so that the surface of the first conductive circuit is flush with a surface of the third dielectric layer; wherein a redundant part of the second conductive circuit and a redundant part of the second dielectric layer of the chip package unit are removed at the same time by circuit grinding technique so that the surface of the second conductive circuit is flush with a surface of the second dielectric layer.

11. A package structure formed by stacking chip package units comprising:
at least one substrate provided with a fifth surface having at least one blind hole and a sixth surface opposite to the fifth surface;
at least one second circuit layer disposed on the sixth surface of the substrate and extending to an inner wall surface of the blind hole of the substrate;
at least one third conductive circuit which is electrically connected with and arranged at the second circuit layer;
at least two chip package units as in claim 1 and stacked vertically while an upper chip package unit and a lower chip package unit of the two chip package units are electrically connected by at least one fourth conductive circuit; wherein the fourth conductive circuit is electrically connected with the second conductive circuit of the upper chip package unit and the first conductive circuit of the lower chip package unit; and
at least one insulating layer arranged at the substrate and covering the chip package units;
wherein chip package unit is electrically connected to the outside by the second circuit layer.

12. The package structure as claimed in claim 11, wherein the package structure further includes an outer bottom protective layer on a bottom thereof.

13. The package structure as claimed in claim 11, wherein the package structure further includes an outer top protective lay on a top thereof.

14. The package structure as claimed in claim 11, wherein the package structure further includes the three chip package units.
